(19) United States
(12) Patent Application Publication
(10) Pub. No.: US 2021/0020483 A1
(43) Pub. Date: Jan. 21, 2021

(54) DIE PICKUP METHOD

(71) Applicant: SEMES CO., LTD., Cheonan-si (KR)

(72) Inventors: Byoung Ho JUNG, Cheonan-si (KR); Chang Jin KIM, Suwon-si (KR); Eung Seok KIM, Cheonan-si (KR)

(73) Assignee: SEMES CO., LTD., Cheonan-si (KR)

(21) Appl. No.: 16/930,941

(22) Filed: Jul. 16, 2020

(30) Foreign Application Priority Data
Jul. 18, 2019 (KR) 10-2019-0086934

(51) Int. Cl. H01L 21/677; H01L 21/68; H01L 21/52; H01L 21/683; H01L 21/78

(52) U.S. Cl. CPC H01L 21/67712; H01L 21/68; H01L 21/78; H01L 21/6836; H01L 21/52

(57) ABSTRACT

A die pickup method is disclosed. The die pickup method is used to pick up dies from a wafer that includes a first array in which a plurality of dies having a length and a width is arranged in a width direction, and a second array in which a plurality of dies is arranged parallel to the first array and having a number of dies greater than that of the first array. The die pickup method includes sequentially picking up dies of the first array in a first width direction from a first die located at a first end of the first array toward a second die located at a second end of the first array, detecting a third die of the second array adjacent to the second die, and detecting a fourth die located at a second end of the second array in the first width direction.

### CROSS-REFERENCE TO RELATED APPLICATION

This application claims the priority benefit of Korean Patent Application No. 10-2019-0086934, filed on Jul. 18, 2019, and all the benefits accruing therefrom under 35 U.S.C. § 119, the contents of which are incorporated by reference in their entirety.

### BACKGROUND

The present invention relates to a die pickup method. More specifically, the present invention relates to a method of picking up dies from a dicing tape of a framed wafer in order to bond the dies on a substrate such as a printed circuit board (PCB) or a lead frame in a die bonding process.

Generally, semiconductor devices may be formed on a silicon wafer used as a semiconductor substrate by repetitively performing a series of manufacturing processes. Semiconductor devices formed on the silicon wafer may be individualized by a dicing process and may be bonded to substrates by a die bonding process.

An apparatus for performing the die bonding process may include a pickup module for picking up the dies from the wafer and a bonding module for bonding the dies on the substrate. The wafer may include a dicing tape on which the dies are attached and a circular ring-shaped mount frame on which the dicing tape is mounted. The pickup module may include a wafer stage for supporting the wafer, a die ejector for separating the dies one by one from the dicing tape, and a pickup unit for picking up a die separated from the dicing tape by the die ejector.

The bonding module may include a substrate stage for supporting the substrate, a bonding head for bonding the dies on the substrate, and a head driving section for moving the bonding head in vertical and horizontal directions. Specifically, the pickup module may transfer the die picked up from the wafer onto a die stage, and the bonding module may pick up the die from the die stage and bond the die onto the substrate.

A camera unit for detecting the dies may be disposed above the wafer stage. After the wafer is loaded onto the wafer stage, the camera unit may detect some of the dies for alignment of the wafer. The wafer stage may be configured to be movable and rotatable, and may align the wafer using location information of the dies detected by the camera unit. After the wafer is aligned, the dies may be sequentially detected and picked up according to a predetermined pickup order.

FIGS. 1 and 2 are schematic views illustrating a die pickup method according to the prior art.

Referring to FIGS. 1 and 2, a wafer 10 may include a plurality of dies 12 arranged in a form of a plurality of rows and columns. Particularly, when the dies 12, such as driver IC elements of a display device, have a relatively large aspect ratio, that is, a relatively long length compared to a width, the wafer 10 may include a plurality of arrays 14 and 16 in which the dies 12 are arranged parallel to each other in a width direction. In this case, in order to reduce the moving distance of the wafer stage for pickup of the dies 12, the pickup order of the dies 12 may be set in the width direction of the dies 12. Meanwhile, mirror dies 18 on which circuit patterns are not formed may be disposed around the dies 12, that is, on edge portions of the wafer 10, and defective dies 20 determined as defective in an electrical inspection process may be disposed among the dies 12.

The pickup order of the dies 12 may be set in a zigzag form. When picking up a last die 12A of an array 14 and detecting a first die 12B of a subsequent array 16, it may be difficult to detect the first die 12B because the first die 12B is relatively far from the last die 12A. For example, when the number of dies in the subsequent array 16 is greater than the number of dies in the previous array 14, the wafer 10 may be moved based on previously given map data such that the first die 12B of the subsequent array 16 is positioned on the die ejector after picking up the last die 12B of the previous array 14. However, as the dies 12 are picked up, deformation of the dicing tape may occur, whereby the position of the first die 12B of the subsequent array 16 may be changed. Further, for the same reason, the first die 12B of the subsequent array 16 may be misdetected. For example, a second die of the subsequent array 16 may be incorrectly detected as the first die 12B, in which case serious defects may occur in semiconductor devices manufactured by bonding the dies of the subsequent array 16.

Further, as shown in FIG. 2, when the number of dies in a subsequent array 24 is less than the number of dies in a previous array 22, it may be difficult to detect a first die 12D of the subsequent array 24 because the first die 12D of the subsequent arrangement 24 is relatively far from a last die 12C of the previous arrangement 22.

### SUMMARY

Embodiments of the present invention provide a die pickup method capable of easily detecting a first die in a subsequent array in a die bonding process.

In accordance with an aspect of the present invention, a die pickup method may be used to pick up dies from a wafer that includes a first array in which a plurality of dies having a length and a width is arranged in a width direction, and a second array in which a plurality of dies is arranged parallel to the first array and having a number of dies greater than that of the first array. The die pickup method may include sequentially picking up dies of the first array in a first width direction from a first die located at a first end of the first array toward a second die located at a second end of the first array, detecting a third die of the second array adjacent to the second die, detecting a fourth die located at a second end of the second array in the first width direction, and sequentially picking up dies of the second array from the fourth die to a fifth die located at a first end of the second array in a second width direction opposite to the first width direction.

In accordance with some embodiments of the present invention, the wafer may include a dicing tape on which the dies are attached, and a die ejector for separating the dies from the dicing tape may be disposed below the dicing tape.

In accordance with some embodiments of the present invention, sequentially picking up the dies of the first array may be performed while moving the wafer in the second width direction so that the dies of the first array are sequentially positioned on the die ejector.

In accordance with some embodiments of the present invention, sequentially picking up the dies of the second array may be performed while moving the wafer in the first width direction so that the dies of the second array are sequentially positioned on the die ejector.

In accordance with some embodiments of the present invention, a camera unit for detecting the dies may be disposed above the wafer, and the dies of the first array and the dies of the second array may be detected by the camera unit before each pickup.

In accordance with some embodiments of the present invention, the die pickup method may further include sequentially detecting dies between the third die and the fourth die in the first width direction after detecting the third die.

In accordance with some embodiments of the present invention, a camera unit for detecting the dies may be disposed above the wafer, and the wafer may be moved so that the third die is positioned under the camera unit after the dies of the first array are picked up, and may then be moved so that the dies between the third die and the fourth die are sequentially positioned under the camera unit.

In accordance with another aspect of the present invention, a die pickup method may be used to pick up dies from a wafer that includes a first array in which a plurality of dies having a length and a width is arranged in a width direction, and a second array in which a plurality of dies is arranged parallel to the first array and having a number of dies smaller than that of the first array. The die pickup method may include sequentially picking up dies of the first array from a first die located at a first end of the first array to a second die of the first array in a first width direction from the first die toward a fourth die located at a second end of the first array, the second die of the first array being located immediately before a third die of the first array adjacent to a fifth die located at a second end of the second array, detecting the fourth die of the first array, sequentially picking up remaining dies of the first array from the fourth die to the third die in a second width direction opposite to the first width direction, and sequentially picking up dies of the second array from the fifth die to a sixth die located at a first end of the second array in the second width direction.

In accordance with some embodiments of the present invention, the wafer may include a dicing tape on which the dies are attached, and a die ejector for separating the dies from the dicing tape may be disposed below the dicing tape.

In accordance with some embodiments of the present invention, sequentially picking up the dies of the first array may be performed while moving the wafer in the second width direction so that the dies of the first array are sequentially positioned on the die ejector.

In accordance with some embodiments of the present invention, sequentially picking up the remaining dies of the first array may be performed while moving the wafer in the first width direction so that the remaining dies of the first array are sequentially positioned on the die ejector.

In accordance with some embodiments of the present invention, sequentially picking up the dies of the second array may be performed while moving the wafer in the first width direction so that the dies of the second array are sequentially positioned on the die ejector.

In accordance with some embodiments of the present invention, a camera unit for detecting the dies may be disposed above the wafer, and the dies and the remaining dies of the first array and the dies of the second array may be detected by the camera unit before each pickup.

In accordance with some embodiments of the present invention, the die pickup method may further include sequentially detecting the third die and dies between the third die and the fourth die in the first width direction after picking up the dies of the first array.

In accordance with some embodiments of the present invention, a camera unit for detecting the dies may be disposed above the wafer, and the wafer may be moved so that the remaining dies of the first array from the third die to the fourth die are sequentially positioned under the camera unit after picking up the dies of the first array.

The above summary of the invention is not intended to describe each illustrated embodiment or every implementation of the present invention. The detailed description and claims that follow more particularly exemplify these embodiments.

### BRIEF DESCRIPTION OF THE DRAWINGS

Embodiments of the present invention can be understood in more detail from the following description taken in conjunction with the accompanying drawings, in which:

FIGS. 1 and 2 are schematic views illustrating a die pickup method according to the prior art;

FIG. 3 is a flowchart illustrating a die pickup method in accordance with an embodiment of the present invention;

FIG. 4 is a schematic view illustrating the die pickup method as shown in FIG. 3;

FIG. 5 is a schematic view illustrating a die pickup apparatus for performing the die pickup method as shown in FIG. 3;

FIG. 6 is a flowchart illustrating a die pickup method in accordance with another embodiment of the present invention; and

FIG. 7 is a schematic view illustrating the die pickup method as shown in FIG. 6.

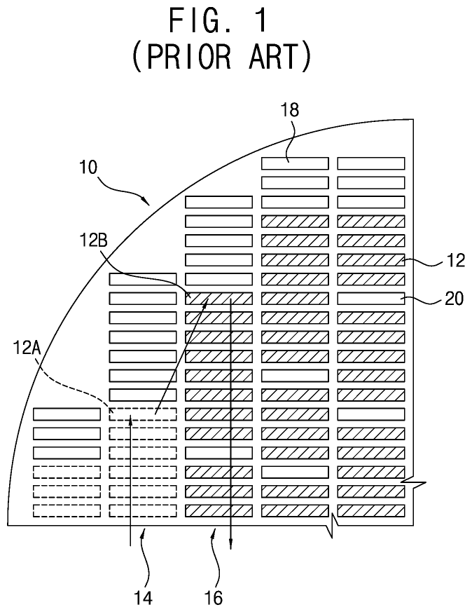

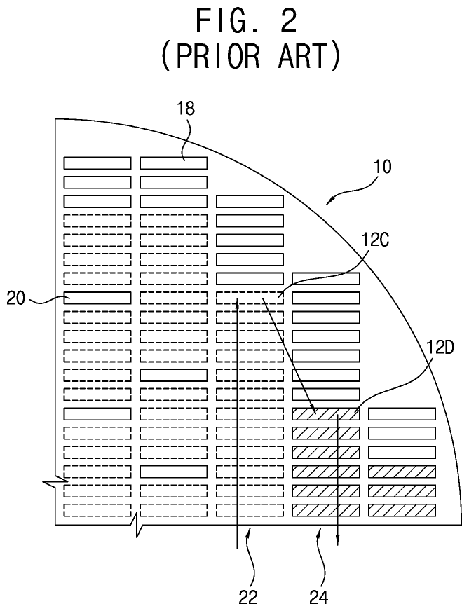

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

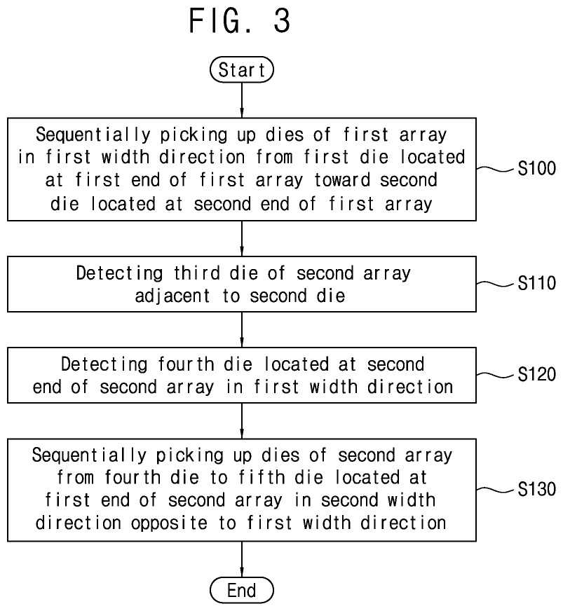

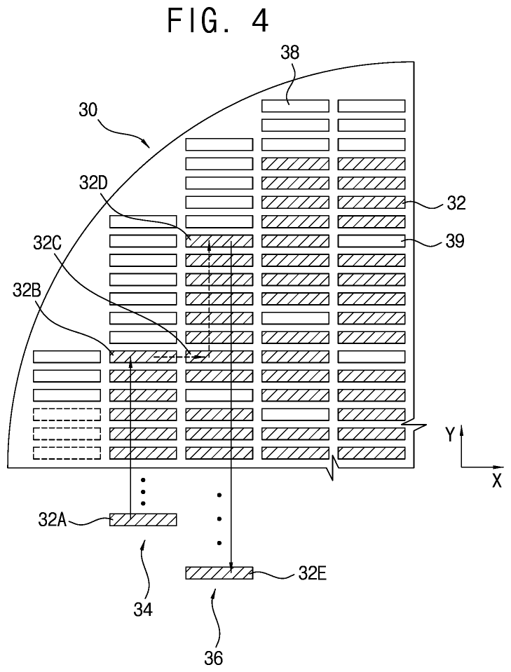

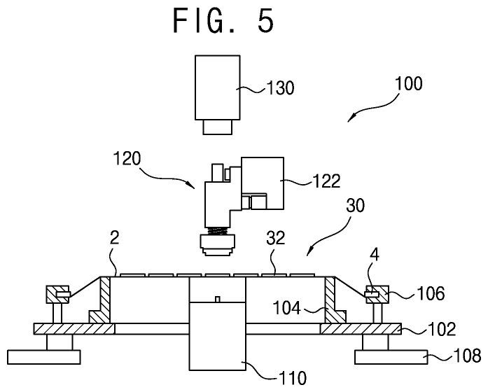

FIG. 3 is a flowchart illustrating a die pickup method in accordance with an embodiment of the present invention, and FIG. 4 is a schematic view illustrating the die pickup method as shown in FIG. 3. FIG. 5 is a schematic view illustrating a die pickup apparatus for performing the die pickup method as shown in FIG. 3.

Referring to FIGS. 3 to 5, a die pickup method in accordance with an embodiment of the present invention may be used to pick up dies 32 from a wafer 30 in a die bonding process for manufacturing semiconductor devices.

The wafer 30 may include a plurality of dies 32 individualized by a dicing process and may be attached on a dicing tape 2. Particularly, the dies 32 may be attached on the dicing tape 2 in rows and columns, and the dicing tape 2 may be mounted on a mount frame 4 having a substantially circular ring shape. For example, the dies 32 may have a length and a width and may be arranged in a width direction. The wafer 30 may include a plurality of arrays 34 and 36 extending parallel to the width direction, for example, in a Y-axis direction. Particularly, the wafer 30 may include a first array 34 having a first number of dies and a second array 36 having a second number of dies greater than the first number of dies. The first array 34 and the second array 36 may be disposed adjacent to each other in a length direction of the dies 32, for example, in an X-axis direction. Further, the wafer 30 may include mirror dies 38 disposed around the dies 32, that is, on edge portions of the wafer 30, and defective dies 39 among the dies 32.

A die pickup apparatus 100 for picking up the dies 32 may include a wafer stage 102 for supporting the wafer 30. The wafer stage 102 may include an expansion ring 104 for supporting the dicing tape 2, clamps 106 for gripping the mount frame 4, and a clamp driving section (not shown) that expands the dicing tape 2 by lowing the clamps 106, and the like.

A die ejector 110 for separating the dies 32 one by one from the dicing tape 2 may be disposed below the wafer 30 supported by the wafer stage 102. The die ejector 110 may include an ejector member for separating a die 32 to be picked up from the dicing tape 2 by pushing the die 32 upward, and the die 32 separated by the die ejector 110 may be picked up by a picker 120.

The picker 120 may be disposed above the wafer 30 in order to pick up the dies 32. For example, the picker 120 may have a vacuum hole for vacuum-absorbing the die 32, and may be moved in horizontal and vertical directions by a picker driving section 122. The die 32 may be transferred on a die stage (not shown) by the picker 120 and the picker driving section 122, and may then be bonded onto a substrate such as a printed circuit board, a lead frame, or the like, by a bonding unit (not shown).

The wafer stage 102 may be moved by a stage driving section 108 in a horizontal direction. Further, the wafer stage 102 may be rotated by the stage driving section 108. The stage driving section 108 may move the wafer stage 102 in the X-axis direction and the Y-axis direction for a position alignment of the wafer 30, and may rotate the wafer stage 102 for an angular alignment of the wafer 30. Further, the stage driving section 108 may move the wafer stage 102 in the horizontal direction for detecting and picking up the dies 32.

A camera unit 130 for detecting the dies 32 may be disposed above the wafer 30 supported by the wafer stage 102. The camera unit 130 may detect position coordinates and an angle of the die 32 to be picked up by imaging the die 32. The stage driving section 108 may align the wafer 30 using the position information of the die 32 detected by the camera unit 130 so that the die 32 is accurately positioned on the die ejector 110. Further, the stage driving section 108 may adjust the angle of the wafer stage 102 to align the angle of the die 32. Particularly, the camera unit 130 may be coaxially disposed with the die ejector 110, and may detect the die 32 positioned on the die ejector 110.

Further, the die pickup apparatus 100 may include a control unit (not shown) for controlling operations of the stage driving section 108, the die ejector 110, the picker 120, the picker driving section 122, the camera unit 130, and the like. For example, the control unit may detect the die 32 to be picked up using the camera unit 130, and may control the operations of the stage driving section 108 using the position information of the die 32 detected by the camera unit 130 so that the die 32 is aligned on the die ejector 110. Further, the control unit may control the operations of the picker 120 and the picker driving section 122 in order to pick up the die 32.

Hereinafter, a die pickup method in accordance with an embodiment of the present invention will be described with reference to the accompanying drawings.

In step S100, dies 32 of the first array 34 may be sequentially picked up from the dicing tape 2 in a first width direction from a first die 32A located at a first end of the first array 34 toward a second die 32B located at a second end of the first array 34. For example, the dies 32 of the first array 34 may be sequentially picked up in the first width direction, for example, in a Y-axis plus direction.

Specifically, the wafer 30 may be moved such that a die 32 to be picked up is positioned on the die ejector 110, and the die 32 may then be detected by the camera unit 130. The position of the die 32 may be corrected based on the position information detected by the camera unit 130, and the die 32 may then be picked up by the die ejector 110 and the picker 120.

After the die 32 is picked up, the wafer 30 may be moved such that a subsequent die 32 is positioned on the die ejector 110. For example, the wafer 30 may be moved in a second width direction opposite to the first width direction, for example, in a Y-axis minus direction. After the subsequent die 32 is positioned on the die ejector 110, detection and pickup of the subsequent die 32 may be performed. As described above, the wafer 30 may be moved in the second width direction such that the dies 32 of the first array 34 are sequentially positioned on the die ejector 110, and the dies 32 of the first array 34 may be sequentially detected and picked up one by one.

In step S110, a third die 32C of the second array 36 adjacent to the second die 32B may be detected. The third die 32C may be disposed adjacent to the second die 32B in a first length direction of the dies 32, for example, in an X-axis plus direction. The wafer 30 may be moved in a second length direction opposite to the first length direction, for example, in an X-axis minus direction, and the third die 32C may then be detected by the camera unit 130.

In step S120, a fourth die 32D which is positioned at a second end of the second array 36 in the first width direction may be detected. For example, the wafer 30 may be moved in the second width direction such that the fourth die 32D is positioned on the die ejector 110, and the camera unit 130 may detect the fourth die 32D positioned on the die ejector 110. Particularly, though not shown in figures, after detecting the third die 32C, a step of sequentially detecting dies 32 between the third die 32C and the fourth die 32D in the first width direction may be performed. That is, from the third die 32C to the fourth die 32D, die detection may be sequentially performed on some dies 32 of the second array 36 in the first width direction. Specifically, the wafer 30 may be moved in the second width direction so that some dies 32 of the second array 36 from the third die 32C to the fourth die 32D are sequentially positioned on the die ejector 110, and the camera unit 130 may sequentially detect some dies 32 of the second array 36 positioned on the die ejector 110.

In step S130, dies 32 of the second array 36 may be sequentially picked up from the dicing tape 2 in the second width direction from the fourth die 32D toward a fifth die 32E located at a first end of the second array 36. For example, the wafer 30 may be moved in the first width direction such that the dies 32 of the second array 36 are sequentially positioned on the die ejector 110, and the dies 32 of the second array 36 may be sequentially detected and picked up one by one.

Meanwhile, when a defective die 39 is detected while sequentially picking up the dies 32 of the first and second arrays 34 and 36, a pickup step for the defective die 39 may be omitted.

In accordance with the present embodiment as described above, after picking up the second die 32B, i.e., the last die, of the first array 34, the third die 32C of the second array 36 adjacent to the second die 32B may be detected, and the fourth die 32D, i.e., the first die of the second array 36 may then be detected by sequentially detecting dies 32 from the third die 32C to the fourth die 32D. Accordingly, misdetection of the first die of the second array 36 may be sufficiently prevented.

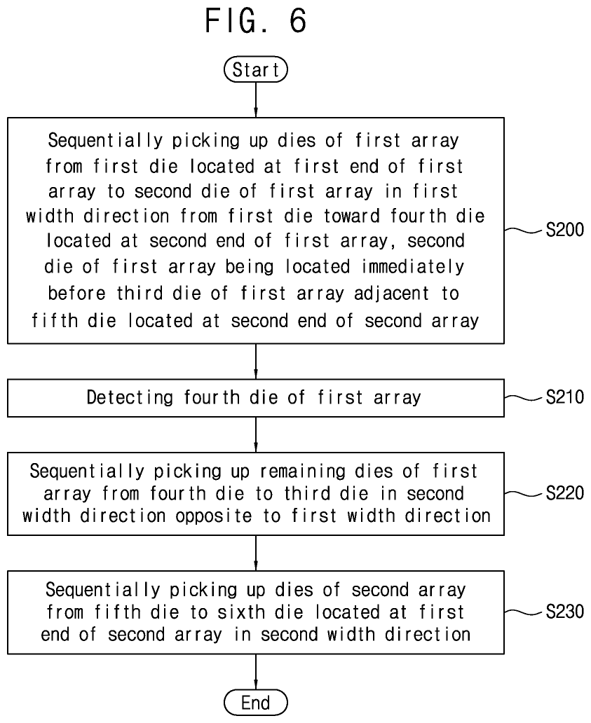

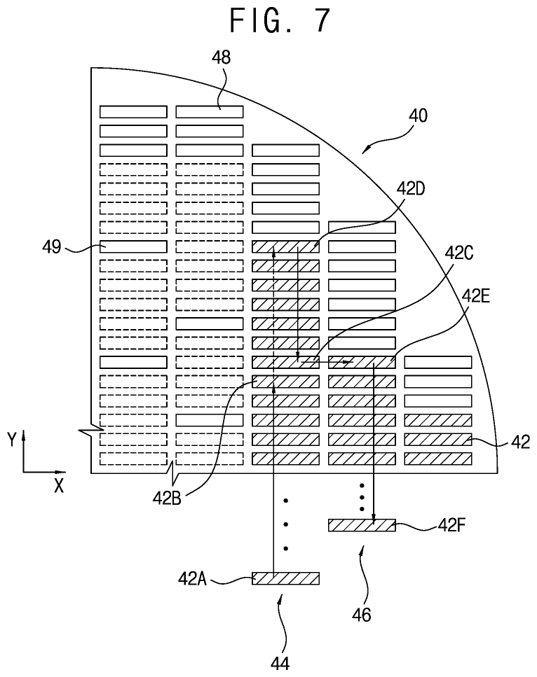

FIG. 6 is a flowchart illustrating a die pickup method in accordance with another embodiment of the present invention, and FIG. 7 is a schematic view illustrating the die pickup method as shown in FIG. 6.

Referring to FIGS. 6 and 7, a die pickup method in accordance with another embodiment of the present invention may be used to pick up dies 42 from a wafer 40 in a die bonding process for manufacturing semiconductor devices. The dies 42 may have a length and a width and may be arranged in a width direction. The wafer 40 may include a plurality of arrays 44 and 46 extending parallel to the width direction, for example, in a Y-axis direction. Particularly, the wafer 40 may include a first array 44 having a first number of dies and a second array 46 having a second number of dies smaller than the first number of dies. The first array 44 and the second array 46 may be disposed adjacent to each other in a length direction of the dies 42, for example, in an X-axis direction. Further, the wafer 40 may include mirror dies 48 disposed around the dies 42, that is, on edge portions of the wafer 40, and defective dies 49 among the dies 42.

In accordance with another embodiment of the present invention, in step S200, some dies 42 of the first array 44 may be sequentially picked up from the dicing tape 2 in a first width direction from a first die 42A located at a first end of the first array 44 toward a fourth die 42D located at a second end of the first array 44, for example, in a Y-axis plus direction. Particularly, some dies 42 from the first die 42A to a second die 42B, which is located immediately before a third die 42C of the first array 44 adjacent to a fifth die 42E located at a second end of the second array 46, may be sequentially picked up one by one. Specifically, the wafer 40 may be moved in a second width direction opposite to the first width direction, for example, in a Y-axis minus direction such that some dies 42 of the first array 44 are sequentially positioned on the die ejector 110, and some dies 42 of the first array 44 may be sequentially detected and picked up one by one.

In step S210, the fourth die 42D located at the second end of the first array 44 in the first width direction may be detected. For example, the wafer 40 may be moved in the second width direction such that the fourth die 42D is positioned on the die ejector 110, and the camera unit 130 may detect the fourth die 42D positioned on the die ejector 110. Particularly, though not shown in figures, after picking up the second die 42B, a step of sequentially detecting the third die 42C and dies 42 between the third die 42C and the fourth die 42D in the first width direction may be performed. That is, from the third die 42C to the fourth die 42D, die detection may be sequentially performed on the remaining dies 42 of the first array 44 in the first width direction. Specifically, the wafer 40 may be moved in the second width direction so that the remaining dies 42 of the first array 44 from the third die 42C to the fourth die 42D are sequentially positioned on the die ejector 110, and the camera unit 130 may sequentially detect the remaining dies 42 of the first array 44 positioned on the die ejector 110.

In step S220, the remaining dies 42 of the first array 44 may be sequentially picked up from the dicing tape 2 in the second width direction from the fourth die 42D toward the third die 42C. For example, the wafer 40 may be moved in the first width direction such that the remaining dies 42 of the first array 44 are sequentially positioned on the die ejector 110, and the remaining dies 42 of the first array 44 may be sequentially detected and picked up one by one.

In step S230, dies 42 of the second array 46 may be sequentially picked up from the dicing tape 2 in the second width direction from the fifth die 42E toward a sixth die 42F located at a first end of the second array 46. For example, the wafer 40 may be moved in the first width direction such that the dies 42 of the second array 46 are sequentially positioned on the die ejector 110, and the dies 42 of the second array 46 may be sequentially detected and picked up one by one.

In accordance with the present embodiment as described above, after the remaining dies 42 of the first array 44 from the fourth die 42D to the third die 42C are detected and picked up one by one, the fifth die 42E of the second array 46 adjacent to the third die 42C in the length direction of the dies 42 may be detected. Accordingly, the fifth die 42E, i.e., the first die of the second array 46 may be easily detected, and further misdetection of the first die of the second array 46 may be sufficiently prevented.

Although the die pickup method has been described with reference to specific embodiments, it is not limited thereto. Therefore, it will be readily understood by those skilled in the art that various modifications and changes can be made thereto without departing from the spirit and scope of the present invention defined by the appended claims.

1. A die pickup method of picking up dies from a wafer that includes a first array in which a plurality of dies having a length and a width is arranged in a width direction, and a second array in which a plurality of dies is arranged parallel to the first array and having a number of dies greater than that of the first array, the method comprising:
sequentially picking up dies of the first array in a first width direction from a first die located at a first end of the first array toward a second die located at a second end of the first array;
detecting a third die of the second array adjacent to the second die;
detecting a fourth die located at a second end of the second array in the first width direction; and
sequentially picking up dies of the second array from the fourth die to a fifth die located at a first end of the second array in a second width direction opposite to the first width direction.

2. The method of claim 1, wherein the wafer includes a dicing tape on which the dies are attached, and
a die ejector for separating the dies from the dicing tape is disposed below the dicing tape.

3. The method of claim 2, wherein sequentially picking up the dies of the first array is performed while moving the wafer in the second width direction so that the dies of the first array are sequentially positioned on the die ejector.

4. The method of claim 2, wherein sequentially picking up the dies of the second array is performed while moving the wafer in the first width direction so that the dies of the second array are sequentially positioned on the die ejector.

5. The method of claim 2, wherein a camera unit for detecting the dies is disposed above the wafer, and
the dies of the first array and the dies of the second array are detected by the camera unit before each pickup.

6. The method of claim 1, further comprising sequentially detecting dies between the third die and the fourth die in the first width direction after detecting the third die.

7. The method of claim 6, wherein a camera unit for detecting the dies is disposed above the wafer, and
the wafer is moved so that the third die is positioned under the camera unit after the dies of the first array are picked up, and then is moved so that the dies between the third die and the fourth die are sequentially positioned under the camera unit.

8. A die pickup method of picking up dies from a wafer that includes a first array in which a plurality of dies having a length and a width is arranged in a width direction, and a second array in which a plurality of dies is arranged parallel to the first array and having a number of dies smaller than that of the first array, the method comprising:
sequentially picking up dies of the first array from a first die located at a first end of the first array to a second die of the first array in a first width direction from the first die toward a fourth die located at a second end of the first array, the second die of the first array being located immediately before a third die of the first array adjacent to a fifth die located at a second end of the second array;
detecting the fourth die of the first array;
sequentially picking up remaining dies of the first array from the fourth die to the third die in a second width direction opposite to the first width direction; and
sequentially picking up dies of the second array from the fifth die to a sixth die located at a first end of the second array in the second width direction.

9. The method of claim 8, wherein the wafer includes a dicing tape on which the dies are attached, and
a die ejector for separating the dies from the dicing tape is disposed below the dicing tape.

10. The method of claim 9, wherein sequentially picking up the dies of the first array is performed while moving the wafer in the second width direction so that the dies of the first array are sequentially positioned on the die ejector.

11. The method of claim 9, wherein sequentially picking up the remaining dies of the first array is performed while moving the wafer in the first width direction so that the remaining dies of the first array are sequentially positioned on the die ejector.

12. The method of claim 9, wherein sequentially picking up the dies of the second array is performed while moving the wafer in the first width direction so that the dies of the second array are sequentially positioned on the die ejector.

13. The method of claim 8, wherein a camera unit for detecting the dies is disposed above the wafer, and
the dies and the remaining dies of the first array and the dies of the second array are detected by the camera unit before each pickup.

14. The method of claim 8, further comprising sequentially detecting the third die and dies between the third die and the fourth die in the first width direction after picking up the dies of the first array.

15. The method of claim 14, wherein a camera unit for detecting the dies is disposed above the wafer, and
the wafer is moved so that the remaining dies of the first array from the third die to the fourth die are sequentially positioned under the camera unit after picking up the dies of the first array.
